(19) United States
(12) Patent Application Publication
(10) Pub. No.: US 2025/0380501 A1
(43) Pub. Date: Dec. 11, 2025

(54) SIDEWALL PINCH-OFF OF WORK FUNCTION METAL

(71) Applicant: INTERNATIONAL BUSINESS MACHINES CORPORATION, Armonk, NY (US)

(72) Inventors: Shay Reboh, Guilderland, NY (US); Takashi Ando, Eastchester, NY (US); Abir Shadman, Albany, NY (US); Debarghya Sarkar, Latham, NY (US); Paul Charles Jamison, Averill Park, NY (US); Junli Wang, Slingerlands, NY (US)

(21) Appl. No.: 18/735,859

(22) Filed: Jun. 6, 2024

(51) Int. Cl. H01L 27/092; H01L 21/762; H01L 29/06; H01L 29/66

(52) U.S. Cl. CPC H10D 84/85; H01L 21/76224; H10D 62/115; H10D 64/017

(57) ABSTRACT

Semiconductor devices include a first stacked set of field effect transistors (FETs), including a first top FET and a first bottom FET. A second stacked set of FETs includes a second top FET and a second bottom FET. A dielectric barrier is between the first stacked set of FETs and the second stacked set of FETs. The dielectric barrier has a narrower width between the first top FET and the second top FET than between the first bottom FET and the second bottom FET.

### BACKGROUND

The present invention generally relates to semiconductor device fabrication and, more particularly, to stacked field effect transistors (FETs).

Stacked FETs provide improved areal device density in semiconductor devices. Such stacked FETs may be particularly useful in devices such as complementary metal-oxide-semiconductor (CMOS) transistors, where a p-type transistor and an n-type transistor are connected to one another by a shared gate and output terminal. N-type transistors and p-type transistors may make use of different materials, such as work function metals, and it can be challenging to selectively form such materials in the correct regions.

For example, when FETs are stacked directly over one another, it can be difficult to selectively etch materials on a top FET without also affecting materials on a bottom FET.

### SUMMARY

A semiconductor device includes a first stacked set of field effect transistors (FETs), including a first top FET and a first bottom FET. A second stacked set of FETs includes a second top FET and a second bottom FET. A dielectric barrier is between the first stacked set of FETs and the second stacked set of FETs. The dielectric barrier has a narrower width between the first top FET and the second top FET than between the first bottom FET and the second bottom FET.

A semiconductor device includes a first stacked set of FETs, including a first top FET with a top work function metal layer and a first bottom FET with a bottom work function metal layer. A second stacked set of FETs includes a second top FET and a second bottom FET. A dielectric barrier is between the first stacked set of FETs and the second stacked set of FETs. The dielectric barrier having a narrower width between the first top FET and the second top FET than between the first bottom FET and the second bottom FET. The top work function metal has having a greater thickness between a channel of the first top FET and the dielectric barrier than a thickness of the bottom work function metal layer between a channel of the first bottom FET and the dielectric barrier.

A semiconductor device includes a first stacked set of FETs, including a first top FET with a top work function metal layer and a first bottom FET with a bottom work function metal layer. A second stacked set of FETs includes a second top FET and a second bottom FET. A shallow trench isolation (STI) structure is in a substrate between the first stacked set of FETs and the second stacked set of FETs. A dielectric barrier is on the STI structure, between the first stacked set of FETs and the second stacked set of FETs. The dielectric barrier includes a dielectric material different from a material of the STI structure and has a narrower width between the first top FET and the second top FET than between the first bottom FET and the second bottom FET. The top work function metal layer has a greater thickness between a channel of the first top FET and the dielectric barrier than a thickness of the bottom work function metal layer between a channel of the first bottom FET and the dielectric barrier.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a set of field effect transistor (FET) stacks having distinct upper and lower work function metals, in accordance with an embodiment of the present invention;

FIG. 2 is a set of cross-sectional views of a step in the fabrication of a semiconductor device having stacked FETs with distinct upper and lower work function metals, in accordance with an embodiment of the present invention;

FIG. 3 is a set of cross-sectional views of a step in the fabrication of a semiconductor device having stacked FETs with distinct upper and lower work function metals, in accordance with an embodiment of the present invention;

FIG. 4 is a set of cross-sectional views of a step in the fabrication of a semiconductor device having stacked FETs with distinct upper and lower work function metals, in accordance with an embodiment of the present invention;

FIG. 5 is a set of cross-sectional views of a step in the fabrication of a semiconductor device having stacked FETs with distinct upper and lower work function metals, in accordance with an embodiment of the present invention;

FIG. 6 is a set of cross-sectional views of a step in the fabrication of a semiconductor device having stacked FETs with distinct upper and lower work function metals, in accordance with an embodiment of the present invention;

FIG. 7 is a set of cross-sectional views of a step in the fabrication of a semiconductor

device having stacked FETs with distinct upper and lower work function metals, in accordance with an embodiment of the present invention;

FIG. 8 is a set of cross-sectional views of a step in the fabrication of a semiconductor device having stacked FETs with distinct upper and lower work function metals, in accordance with an embodiment of the present invention;

FIG. 9 is a set of cross-sectional views of a step in the fabrication of a semiconductor device having stacked FETs with distinct upper and lower work function metals, in accordance with an embodiment of the present invention;

FIG. 10 is a set of cross-sectional views of a step in the fabrication of a semiconductor device having stacked FETs with distinct upper and lower work function metals, in accordance with an embodiment of the present invention;

FIG. 11 is a set of cross-sectional views of a step in the fabrication of a semiconductor device having stacked FETs with distinct upper and lower work function metals, in accordance with an embodiment of the present invention;

FIG. 12 is a set of cross-sectional views of a step in the fabrication of a semiconductor device having stacked FETs with distinct upper and lower work function metals, in accordance with an embodiment of the present invention;

FIG. 13 is a set of cross-sectional views of a step in the fabrication of a semiconductor device having stacked FETs with distinct upper and lower work function metals, in accordance with an embodiment of the present invention;

FIG. 14 is a set of cross-sectional views of a step in the fabrication of a semiconductor device having stacked FETs with distinct upper and lower work function metals, in accordance with an embodiment of the present invention;

FIG. 15 is a block/flow diagram of a method of fabricating a semiconductor device having stacked FETs with distinct upper and lower work function metals, in accordance with an embodiment of the present invention; and

FIG. 16 is a block/flow diagram of a method of fabricating a semiconductor device having stacked FETs with distinct upper and lower work function metals, in accordance with an embodiment of the present invention.

### DETAILED DESCRIPTION

Stacked field effect transistors (FETs) may be formed with a first transistor type (e.g., n-type or p-type) over a complementary second transistor type. A top FET and a bottom FET may have different work function metals, selected to provide appropriate electrical properties for the respective FETs. A dielectric structure may be formed between neighboring devices, for example in a gate cut region. The presence of the dielectric structure causes deposition of a first work function metal layer, for example on the bottom FET, to pinch off between the bottom FET and the dielectric structure. The dielectric structure may be narrower by the top FET than by the bottom FET, so that the first work function metal layer may be etched away from the top FET without removing it from the bottom FET. A second work function metal layer can then be deposited on the top FET. The two work function metal layers may contact one another, providing an electrically connected gate for the stacked FETs.

According to an aspect of the invention, there is provided a semiconductor device that includes a first stacked set of field effect transistors (FETs), including a first top FET and a first bottom FET. A second stacked set of FETs includes a second top FET and a second bottom FET. A dielectric barrier is between the first stacked set of FETs and the second stacked set of FETs. The dielectric barrier has a narrower width between the first top FET and the second top FET than between the first bottom FET and the second bottom FET. The dielectric barrier's different widths make it possible to deposit material on the bottom FETs with a deposition process that pinches off in the space between the bottom FETs and the dielectric barrier. Material may then be etched away from the top FETs without damaging the bottom FETs. As a result, the top FETs may be formed with materials that provide different electrical properties as compared to the bottom FETs.

In embodiments, the first bottom FET includes a bottom work function metal layer and the first bottom top FET includes a top work function metal layer. The top work function metal layer has a greater thickness between a channel of the first top FET and the dielectric barrier than a thickness of the bottom work function metal layer between a channel of the first bottom FET and the dielectric barrier. The greater thickness of the top work function metal is a result of the differing thicknesses of the dielectric barrier. The use of different work function metal layers makes it possible to tune properties of the top FETs and bottom FETs.

In embodiments, the bottom work function metal layer has a different polarity as compared to the top work function metal layer. The use of different polarity work function metal layers makes it possible to create differing FET types (e.g., n-type and p-type FETs) for the top FETs and bottom FETs.

In embodiments, the top work function metal layer is in direct contact with the bottom work function metal layer. Putting the work function metal layers in direct contact electrically ties the gates of the top FETs to the gates of the respective bottom FETs, for example when a complementary transistor device is needed.

In embodiments, the dielectric barrier is in direct contact with the top work function metal layer and the bottom work function metal layer. The dielectric barrier serves as a electrical insulation between neighboring stacks of FETs.

In embodiments, the top work function metal layer has a second thickness in a region between the dielectric barrier and a dielectric separation layer that separates the first top FET from the first bottom FET, the second thickness being the same as the thickness of the bottom work function metal layer between the first bottom FET and the dielectric barrier. The second thickness of the top work function metal layer fills a space between the dielectric barrier and the dielectric separation layer, where the first work function metal layer pinched off and was partially etched back. This creates a connection between the gate of the top FET and the gate of the bottom FET.

In embodiments, the dielectric barrier has a stepped profile between a narrower top portion and a thicker bottom portion. This stepped profile provides the differing widths of the dielectric barrier.

In embodiments, a step of the stepped profile is at a height between the first top FET and the first bottom FET. This height of the step causes the first work function metal layer to pinch off at a position where the first work function metal layer can be preserved from etches on the top FET.

In embodiments, a shallow trench isolation (STI) structure is in a substrate between the first stacked set of FETs and the second stacked set of FETs and is formed from a dielectric material different from a material of the dielectric barrier. The STI structure electrically separates adjacent stacks of FETs from current leakage through the substrate.

According to an aspect of the invention, there is provided a semiconductor device that includes a first stacked set of FETs, including a first top FET with a top work function metal layer and a first bottom FET with a bottom work function metal layer. A second stacked set of FETs includes a second top FET and a second bottom FET. A dielectric barrier is between the first stacked set of FETs and the second stacked set of FETs. The dielectric barrier having a narrower width between the first top FET and the second top FET than between the first bottom FET and the second bottom FET. The top work function metal has having a greater thickness between a channel of the first top FET and the dielectric barrier than a thickness of the bottom work function metal layer between a channel of the first bottom FET and the dielectric barrier. The dielectric barrier's different widths make it possible to deposit material on the bottom FETs with a deposition process that pinches off in the space between the bottom FETs and the dielectric barrier. Material may then be etched away from the top FETs without damaging the bottom FETs. As a result, the top FETs may be formed with materials that provide different electrical properties as compared to the bottom FETs. The greater thickness of the top work function metal is a result of the differing thicknesses of the dielectric barrier. The use of different work function metal layers makes it possible to tune properties of the top FETs and bottom FETs.

In embodiments, the bottom work function metal layer has a different polarity as compared to the top work function metal layer. The use of different polarity work function metal layers makes it possible to create differing FET types (e.g., n-type and p-type FETs) for the top FETs and bottom FETs.

In embodiments, the top work function metal layer is in direct contact with the bottom work function metal layer. Putting the work function metal layers in direct contact electrically ties the gates of the top FETs to the gates of the respective bottom FETs, for example when a complementary transistor device is needed.

In embodiments, the dielectric barrier is in direct contact with the top work function metal layer and the bottom work function metal layer. The dielectric barrier serves as a electrical insulation between neighboring stacks of FETs.

In embodiments, the top work function metal layer has a second thickness in a region between the dielectric barrier and a dielectric separation layer that separates the first top FET from the first bottom FET, the second thickness being the same as the thickness of the bottom work function metal layer between the first bottom FET and the dielectric barrier. The second thickness of the top work function metal layer fills a space between the dielectric barrier and the dielectric separation layer, where the first work function metal layer pinched off and was partially etched back. This creates a connection between the gate of the top FET and the gate of the bottom FET.

In embodiments, the dielectric barrier has a stepped profile between a narrower top portion and a thicker bottom portion. This stepped profile provides the differing widths of the dielectric barrier.

In embodiments, a step of the stepped profile is at a height between the first top FET and the first bottom FET. This height of the step causes the first work function metal layer to pinch off at a position where the first work function metal layer can be preserved from etches on the top FET.

In embodiments, a shallow trench isolation (STI) structure is in a substrate between the first stacked set of FETs and the second stacked set of FETs and is formed from a dielectric material different from a material of the dielectric barrier. The STI structure electrically separates adjacent stacks of FETs from current leakage through the substrate.

According to an aspect of the invention, there is provided a semiconductor device that includes a first stacked set of FETs, including a first top FET with a top work function metal layer and a first bottom FET with a bottom work function metal layer. A second stacked set of FETs includes a second top FET and a second bottom FET. A shallow trench isolation (STI) structure is in a substrate between the first stacked set of FETs and the second stacked set of FETs. A dielectric barrier is on the STI structure, between the first stacked set of FETs and the second stacked set of FETs. The dielectric barrier includes a dielectric material different from a material of the STI structure and has a narrower width between the first top FET and the second top FET than between the first bottom FET and the second bottom FET. The top work function metal layer has a greater thickness between a channel of the first top FET and the dielectric barrier than a thickness of the bottom work function metal layer between a channel of the first bottom FET and the dielectric barrier. The dielectric barrier's different widths make it possible to deposit material on the bottom FETs with a deposition process that pinches off in the space between the bottom FETs and the dielectric barrier. Material may then be etched away from the top FETs without damaging the bottom FETs. As a result, the top FETs may be formed with materials that provide different electrical properties as compared to the bottom FETs. The greater thickness of the top work function metal is a result of the differing thicknesses of the dielectric barrier. The use of different work function metal layers makes it possible to tune properties of the top FETs and bottom FETs.

In embodiments, a step of the stepped profile is at a height between the first top FET and the first bottom FET. This height of the step causes the first work function metal layer to pinch off at a position where the first work function metal layer can be preserved from etches on the top FET.

In embodiments, a shallow trench isolation (STI) structure is in a substrate between the first stacked set of FETs and the second stacked set of FETs and is formed from a dielectric material different from a material of the dielectric barrier. The STI structure electrically separates adjacent stacks of FETs from current leakage through the substrate.

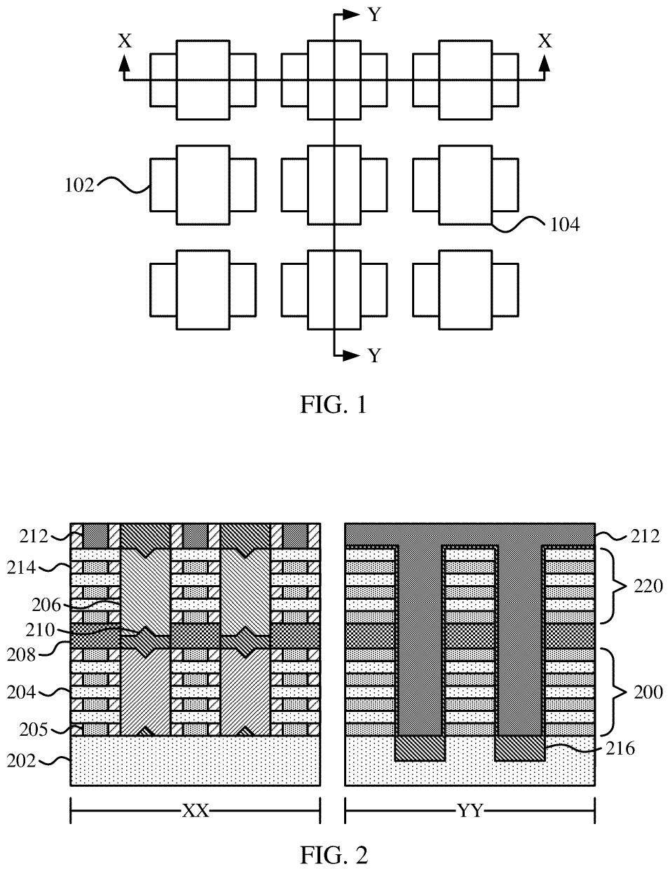

Referring now to FIG. 1, a top-down view of a semiconductor device is shown. The device includes channels 102 and gates 104 for stacked FETs. This view shows two cross-sectional views that illustrate different features of the device. The XX cross-section cuts across regions where the source/drain regions of the stacked FETs will be formed, while the YY cross-section cuts along the gates 104.

It should be understood that the drawings herein are not necessarily drawn to scale, and that the scale between different views may not be consistent. The drawings are described herein to illustrate qualitative features and structural relationships—the relative proportions of structures shown therein should not be interpreted as being limiting.

Referring now to FIG. 2, a set of cross-sectional views is shown of a step in the fabrication of a semiconductor device. Stacked FETs are formed over a semiconductor substrate 202, including bottom FETs 200 and top FETs 220. The bottom FETs 200 and the top FETs 220 include channel layers 204 and, at this point in processing, sacrificial semiconductor layers 205. Source/drain structures 206 have been formed from exposed sidewalls of the channel layers 204, with inner spacers 214 separating the sacrificial semiconductor layers 205 from the source/drain structures 206. Dielectric separation layers 208 separate the top FETs 220 from the bottom FETs 200.

An interlayer dielectric 210 fills a space around and between the source/drain structures 206 of the top FETs 220 and the bottom FETs 200. Dummy gates 212 are formed over the channel layers 204. The dummy gates 212 extend down to the substrate 202 in regions laterally between stacked FETs, with shallow trench isolation (STI) regions 216 being formed in the substrate 202 to provide electrical isolation between neighboring devices.

The semiconductor substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 202 may also be a semiconductor on insulator (SOI) substrate.

The channel layers 204 and the sacrificial semiconductor layers 205 may be formed by successive stages of epitaxial growth from the surface of the semiconductor substrate 202. The channel layers 204 may be formed from silicon, while the sacrificial semiconductor layers 205 may be formed from silicon germanium. The materials of the semiconductor substrate 202, the channel layers 204, and the sacrificial semiconductor layers 205 may be selected to provide crystallographic compatibility for the epitaxial growth process. After epitaxial growth, the semiconductor layers may be photolithographically patterned to form stacks of channel layers 204 and sacrificial semiconductor layers 205 over the substrate 202.

The terms “epitaxial growth” and/or “epitaxial deposition” mean the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The photolithographic patterning may produce a pattern by applying a photoresist to the surface to be etched. The photoresist may be exposed to a pattern of radiation to cause the photoresist to cure. The pattern may be developed into the photoresist utilizing a resist developer. Once the patterning of the photoresist is completed, the sections covered by the photoresist are protected while the exposed regions are removed using a selective etching process that removes the unprotected regions.

As used herein, the term “selective” in reference to a material removal process denotes that the rate of material removal for a first material is greater than the rate of removal for at least another material of the structure to which the material removal process is being applied. Any appropriate selective anisotropic etch may be used to form the stacks, such as reactive ion etching (RIE). RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface.

The inner spacers 214 may be formed by recessing the sacrificial semiconductor layers 205 with respect to the channel layers 204, for example using a selective isotropic etch. Dielectric material, such as silicon nitride, may then be conformally deposited using a chemical vapor deposition (CVD) or atomic layer deposition (ALD) to fill the recesses. Any excess of this dielectric material may be removed from the side surfaces of the channel layers 204 using a selective anisotropic etch.

The source/drain structures 206 may be epitaxially grown from the exposed side surfaces of the channel layers 204 and may be doped in situ. The top FETs 220 may have a different polarity as compared to the bottom FETs 200, for example with one set of FETs being n-type FETs and with the other set of FETs being p-type FETs. The dopants of the source/drain structures 206 may therefore differ in accordance with their respective device polarities.

The dummy gates 212 may be formed from any appropriate material that may be selectively etched with respect to the channel layers 204. For example, polycrystalline silicon may be used to fill this role. The dummy gates 212 at this stage fill the space between devices, as shown in cross-section YY.

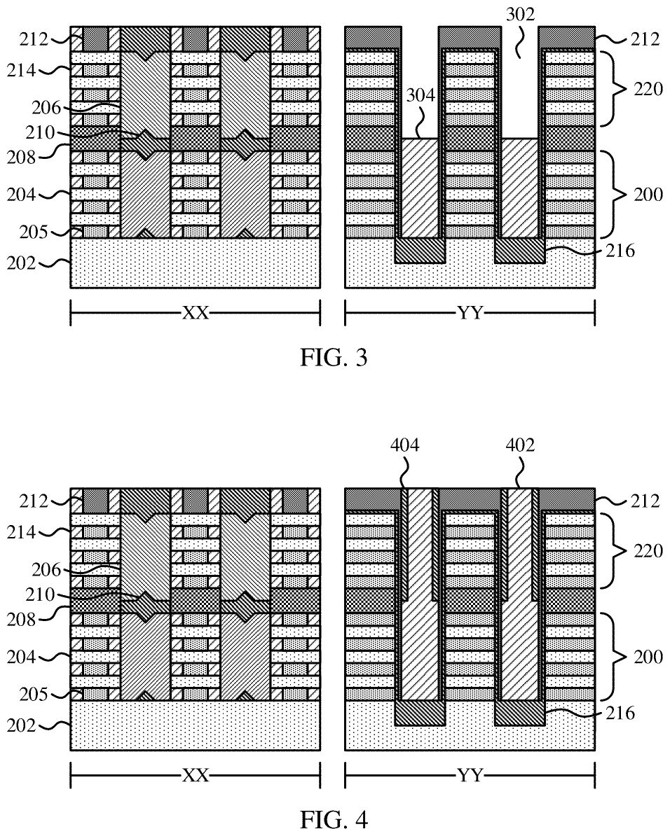

Referring now to FIG. 3, a set of cross-sectional views is shown of a step in the fabrication of a semiconductor device. Openings 302 are etched into the dummy gates 212 using a selective anisotropic etch that exposes the STI regions 216. The openings may be filled with a dielectric material, such as silicon nitride, using any appropriate deposition process, such as CVD, ALD, physical vapor deposition (PVD), or gas cluster ion beam (GCIB) deposition. The deposited dielectric material is etched back to form dielectric plugs 304 using a selective, anisotropic etch.

CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 4, a set of cross-sectional views is shown of a step in the fabrication of a semiconductor device. A sidewall liner 404 is formed by conformally depositing material on exposed surfaces using, e.g., CVD or ALD, using any material with appropriate etch selectivity, such as silicon dioxide. The material is etched away from horizontal surfaces using a selective anisotropic etch, leaving the sidewall liner 404. The remainder of the opening 302 is then filled with additional dielectric material to extend the plug 304 to form dielectric barrier 402, using any appropriate deposition process. The dielectric barrier 402 has a stepped profile, with a top portion that has a narrower width than a bottom portion, with a sharp transition between the top portion and a bottom portion.

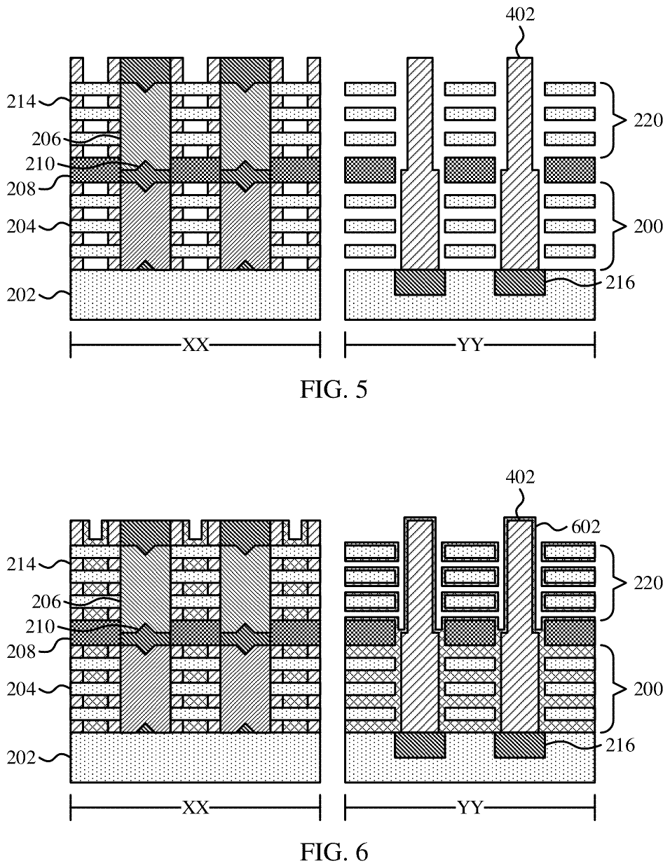

Referring now to FIG. 5, a set of cross-sectional views is shown of a step in the fabrication of a semiconductor device. The dummy gates 212 are selectively etched away. The sidewall liners 404 are similarly etched away using a selective etch, leaving sidewalls of the dielectric barrier 402 and of the sacrificial semiconductor layers 205 exposed. The sacrificial semiconductor layers 205 are selectively etched away using an isotropic etch that leaves the channel layers 204 suspended.

Referring now to FIG. 6, a set of cross-sectional views is shown of a step in the fabrication of a semiconductor device. A layer of gate dielectric material (not shown) is conformally deposited on exposed surfaces, for example using a CVD or ALD deposition process, followed by a layer 602 of first work function metal. Notably the thickness of the layer 602 is larger between the dielectric barrier 402 and the top FETs 220 than it is between the dielectric barrier 402 and the bottom FETs 200.

The gate dielectric material may be, for example, a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The first work function metal may be selected in accordance with the polarity of the bottom FETs 200. A “p-type work function metal” is a metal layer that effectuates a p-type threshold voltage shift. In one embodiment, the work function of the p-type work function metal layer ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In one embodiment, a p-type work function metal layer may be formed from titanium nitride, titanium aluminum nitride, ruthenium, platinum, molybdenum, cobalt, and alloys and combinations thereof.

As used herein, an “n-type work function metal” is a metal layer that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In one embodiment, the work function of the n-type work function metal layer ranges from 4.1 eV to 4.3 eV. In one embodiment, the n-type work function metal layer is formed from at least one of titanium aluminum, tantalum nitride, titanium nitride, hafnium nitride, hafnium silicon, or combinations thereof. It should be understood that titanium nitride may play the role of an n-type work function metal or a p-type work function metal, depending on the conditions of its deposition.

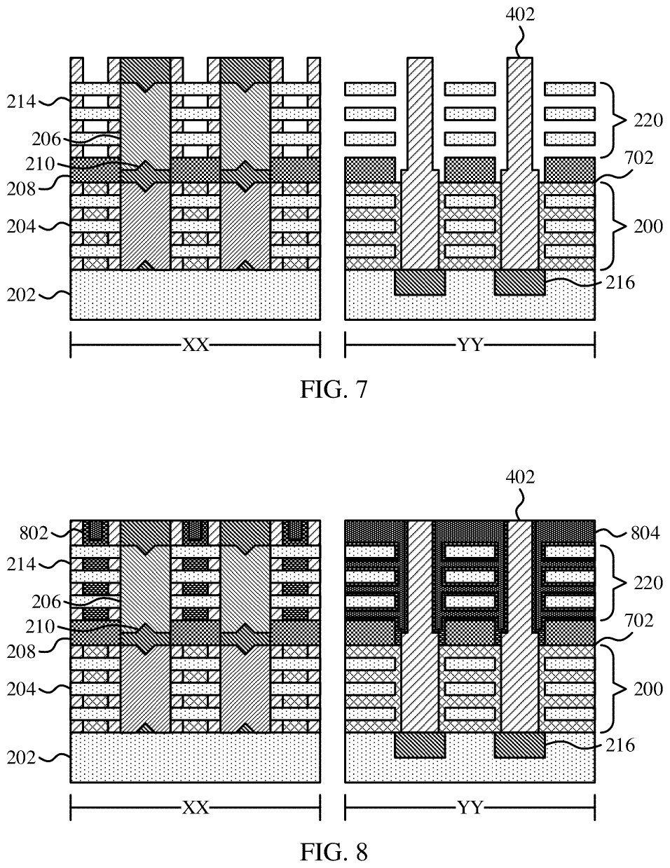

Referring now to FIG. 7, a set of cross-sectional views is shown of a step in the fabrication of a semiconductor device. The layer 602 of first work function metal is etched back using a selective isotropic etch. The etch removes the first work function metal from between the channel layers 204 of the top FETs 220, but works more slowly in the narrow space between the dielectric barriers 402 and the bottom FETs 200. This preserves leaves bottom work function metal layer 702 on the bottom FETs 200, while exposing the channels of the top FETs 220.

Referring now to FIG. 8, a set of cross-sectional views is shown of a step in the fabrication of a semiconductor device. A top work function metal layer 802 is conformally deposited on the top FETs 220. The material of the top work function metal layer 802 may have a polarity opposite to the polarity of the bottom work function metal layer 702. Thus, if the bottom work function metal layer 702 is formed from a p-type work function metal, then the top work function metal layer 802 may be formed from an n-type work function metal.

Additional conductive material may be deposited to fill space over the top work function metal layer 802 to form gate conductors 804. The gate conductors 804 may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductors 804 may alternatively be formed from a doped semiconductor material such as, e.g., doped polysilicon.

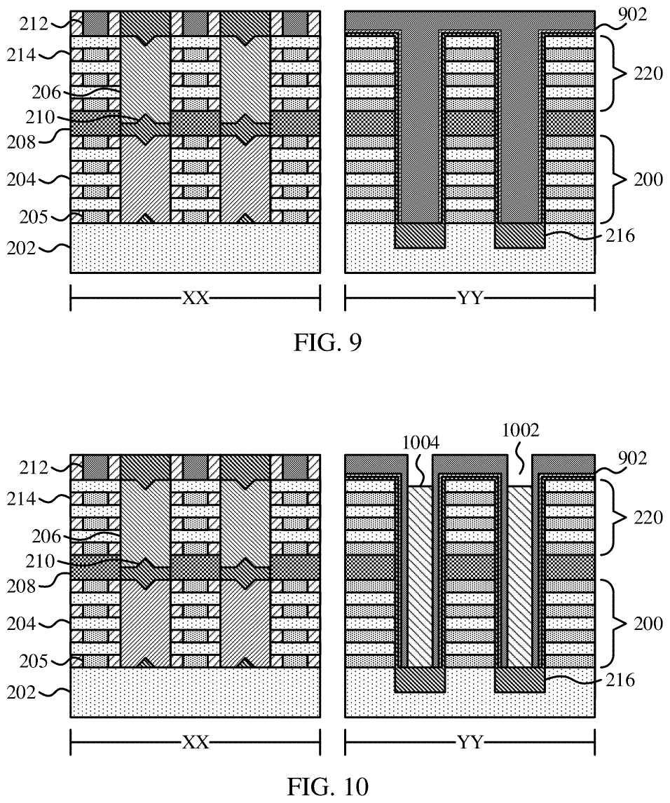

Referring now to FIG. 9, a set of cross-sectional views is shown of a step in an alternative process for the fabrication of a semiconductor device. Similar to the structure of FIG. 2, this view shows top FETs 220 and bottom FETs 200, but has an additional liner layer 902 under the dummy gates 212. The liner layer 902 may be formed from any material having appropriate etch selectivity, such as boron-doped silicon.

Referring now to FIG. 10, a set of cross-sectional views is shown of a step in an alternative process for the fabrication of a semiconductor device. Openings 1002 are selectively and anisotropically etched through the dummy gates 212. Organic planarizing material is filled in the openings 1002 by any appropriate deposition process and is then recessed by any appropriate etching process to form carbon-based planarizing layers 1004. The carbon-based planarizing layers 1004 are recessed to a height that is at or below a top height of the liner layer 902 and that is above a top height of the bottom FETs 200.

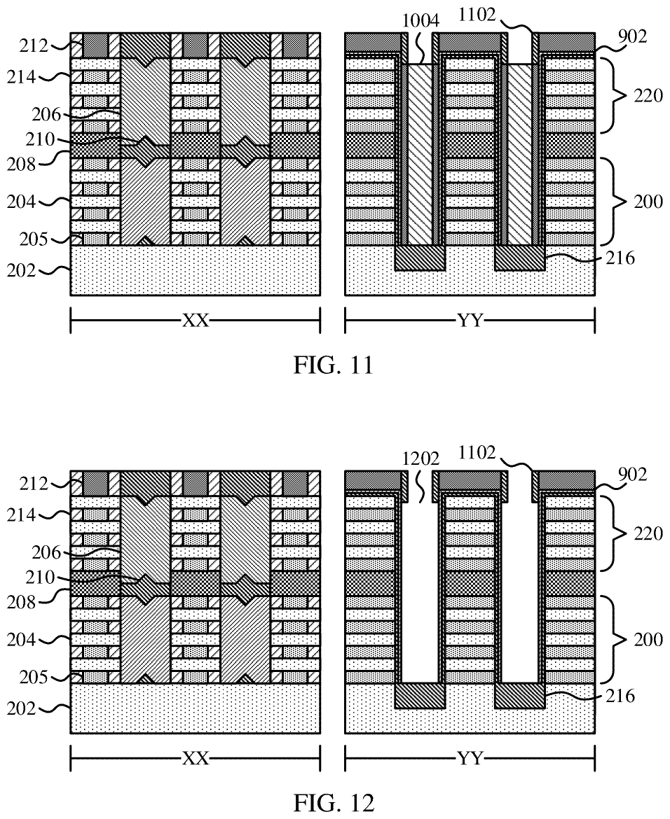

Referring now to FIG. 11, a set of cross-sectional views is shown of a step in an alternative process for the fabrication of a semiconductor device. Exposed surfaces of the dummy gates 212 may be oxidized, for example using a plasma oxidizing process, to convert polycrystalline silicon into silicon dioxide. This forms dielectric sidewalls 1102 in the openings 1002.

Referring now to FIG. 12, a set of cross-sectional views is shown of a step in an alternative process for the fabrication of a semiconductor device. The carbon-based planarizing layers 1004 are removed, for example using a selective etch or ashing process. Exposed portions of the dummy gates 212 that remain within the openings 1002 may be removed using, e.g., an isotropic chemical etch that exposes the liner layer 902 in expanded openings 1202. Although not shown, additional layers may be formed over the top surface of the dummy gates 212 to prevent etching of the dummy gates 212 from the top during this process.

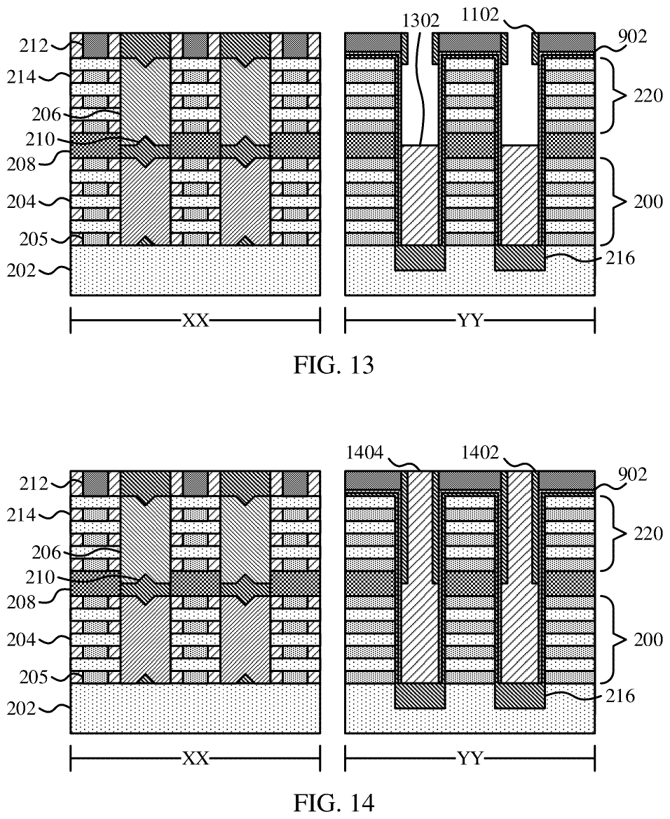

Referring now to FIG. 13, a set of cross-sectional views is shown of a step in an alternative process for the fabrication of a semiconductor device. Dielectric material is deposited in the expanded openings 1202 using a conformal deposition process and is then etched back to form dielectric plugs 1302, for example to a height that exceeds a top height of the bottom FETs 200.

Referring now to FIG. 14, a set of cross-sectional views is shown of a step in an alternative process for the fabrication of a semiconductor device. The dielectric sidewalls 1102 are selectively etched away, and are replaced by conformal deposition of dielectric material (e.g., silicon dioxide) to form extended sidewalls 1402. Excess dielectric material can be anisotropically removed from horizontal surfaces using a selective anisotropic etch. A selectively etchable dielectric material, may then be filled in the expanded openings 1202 using any appropriate conformal deposition process to form dielectric barriers 1404. As above, the dielectric barriers 1404 have a narrower width by the top FETs 220 than their width by the bottom FETs 200.

From this point, the dummy gates 212 may be etched away, along with the liner layer 902 and the extended sidewalls 1402 to expose sidewalls of the dielectric barrier 402 and the sacrificial semiconductor layers 205. The sacrificial semiconductor layers 205 may be etched away with a selective isotropic etch, bringing the alternative process in line with the structure of FIG. 5. From this point forward, processing may continue as described above.

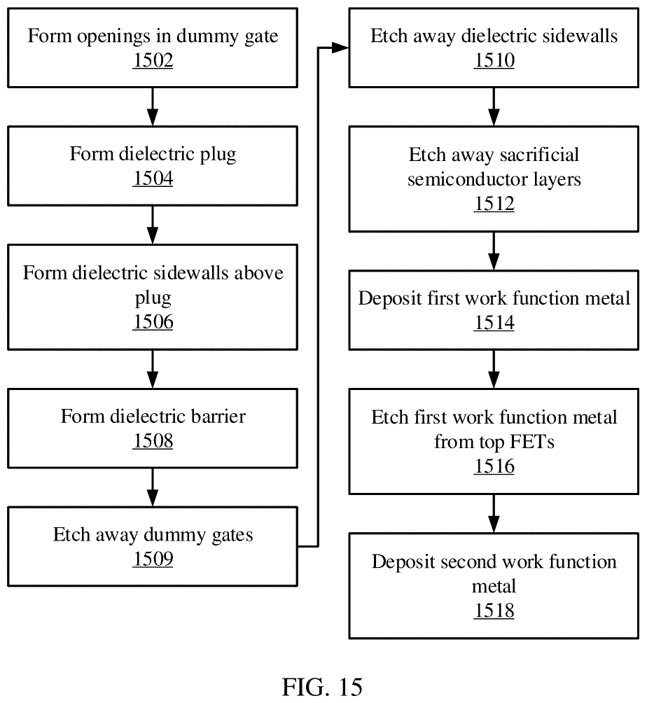

Referring now to FIG. 15, a method of forming a semiconductor device with stacked FETs is shown. After the stacks of alternating channel layers 204 and sacrificial semiconductor layers 205 are formed, with dummy gates 212 as shown above, block 1502 anisotropically etches opening 302 in the dummy gates 212. Block 1504 forms a dielectric plug in the opening 302, for example by depositing silicon nitride and then etching the silicon nitride back to a height between the top FETs 220 and the bottom FETs 200.

Block 1506 forms sidewall liners 404 in the opening 302, for example by conformally depositing silicon dioxide and then anisotropically etching the silicon dioxide from horizontal surfaces. Block 1508 deposits additional dielectric material, such as silicon nitride, into the openings 302 to add to the dielectric plug 304, forming dielectric barrier 402.

Block 1509 etches away the dummy gates 212, block 1510 etches away the sidewall liners 404, and block 1512 etches away the sacrificial semiconductor layers 205 in respective selective etches. Block 1514 conformally deposits a first work function metal that covers the channel layers 204 of the top FETs 220 and the bottom FETs 200 and block 1516 etches the first work function metal away from the top FETs 220. The narrow gap between the dielectric barrier 402 and the bottom FETs 200 prevents the etch of the first work function metal from reaching the lower layers, producing bottom work function metal layer 702. Block 1518 then conformally deposits second work function metal to form top work function metal layer 802. Additional processing steps may form gate conductor 804 and any appropriate electrical contacts to the top FETs 220 and the bottom FETs 200.

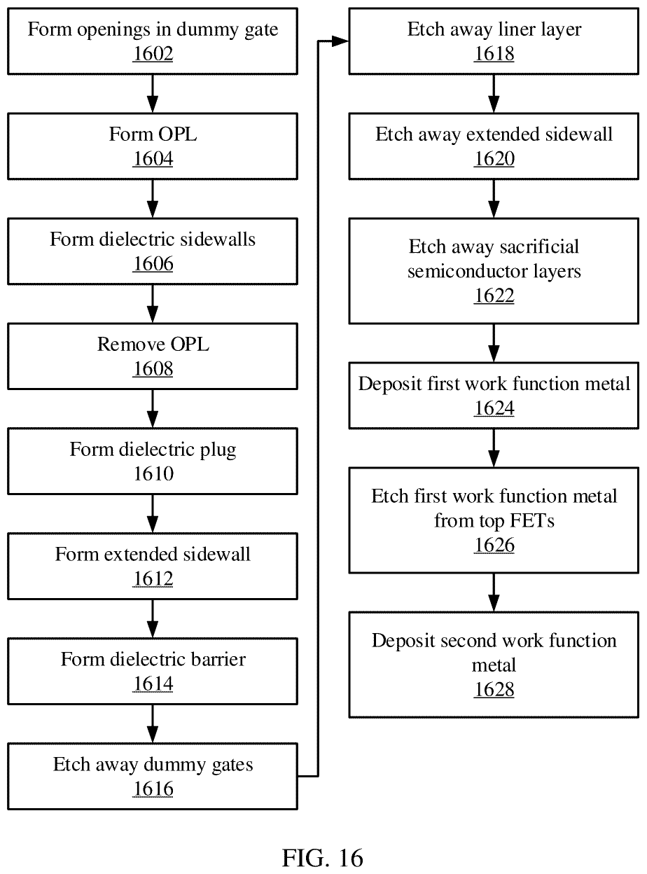

Referring now to FIG. 16, a method of forming a semiconductor device with stacked FETs is shown. After the stacks of alternating channel layers 204 and sacrificial semiconductor layers 205 are formed, with dummy gates 212 and a liner layer 902 as shown above, block 1602 anisotropically etches opening 1002 in the dummy gates 212. Block 1604 forms carbon-based planarizing layers 1004 in opening 1002 and block 1606 forms dielectric sidewalls 1102 on sidewalls of the opening 1002, for example by oxidizing polycrystalline silicon of the dummy gates 212 to form silicon dioxide. Block 1608 removes the carbon-based planarizing layers 1004, for example by a selective etch or by ashing to produce expanded openings 1202.

Block 1610 forms a dielectric plug 1302 in the opening 302, for example by depositing silicon nitride and then etching the silicon nitride back to a height between the top FETs 220 and the bottom FETs 200. Block 1506 forms extended sidewalls 1402, for example by removing the dielectric sidewalls and 1102, conformally forming dielectric material, and etching the dielectric material away from horizontal surfaces. Block 1614 deposits additional dielectric material, such as silicon nitride, into the expanded openings 1202 to add to the dielectric plug 1302, forming dielectric barrier 1404.

Block 1616 etches away the dummy gates 212, block 1618 etches away the liner layer 902, block 1620 etches away the extended sidewalls 1402, and block 1622 etches away the sacrificial semiconductor layers 205 in respective selective etches. Block 1624 conformally deposits a first work function metal that covers the channel layers 204 of the top FETs 220 and the bottom FETs 200 and block 1626 etches the first work function metal away from the top FETs 220. The narrow gap between the dielectric barrier 402 and the bottom FETs 200 prevents the etch of the first work function metal from reaching the lower layers, producing bottom work function metal layer 702. Block 1628 then conformally deposits second work function metal to form top work function metal layer 802. Additional processing steps may form gate conductor 804 and any appropriate electrical contacts to the top FETs 220 and the bottom FETs 200.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper.” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of sidewall pinch-off of work function metal (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first stacked set of field effect transistors (FETs), including a first top FET and a first bottom FET;
a second stacked set of FETs, including a second top FET and a second bottom FET; and
a dielectric barrier between the first stacked set of FETs and the second stacked set of FETs, the dielectric barrier having a narrower width between the first top FET and the second top FET than between the first bottom FET and the second bottom FET.

2. The semiconductor device of claim 1, wherein the first bottom FET includes a bottom work function metal layer and the first bottom top FET includes a top work function metal layer, the top work function metal layer having a greater thickness between a channel of the first top FET and the dielectric barrier than a thickness of the bottom work function metal layer between a channel of the first bottom FET and the dielectric barrier.

3. The semiconductor device of claim 2, wherein the bottom work function metal layer has a different polarity as compared to the top work function metal layer.

4. The semiconductor device of claim 2, wherein the top work function metal layer is in direct contact with the bottom work function metal layer.

5. The semiconductor device of claim 2, wherein the dielectric barrier is in direct contact with the top work function metal layer and the bottom work function metal layer.

6. The semiconductor device of claim 2, wherein the top work function metal layer has a second thickness in a region between the dielectric barrier and a dielectric separation layer that separates the first top FET from the first bottom FET, the second thickness being the same as the thickness of the bottom work function metal layer between the first bottom FET and the dielectric barrier.

7. The semiconductor device of claim 1, wherein the dielectric barrier has a stepped profile between a narrower top portion and a thicker bottom portion.

8. The semiconductor device of claim 7, wherein a step of the stepped profile is at a height between the first top FET and the first bottom FET.

9. The semiconductor device of claim 1, further comprising a shallow trench isolation (STI) structure in a substrate between the first stacked set of FETs and the second stacked set of FETs that is formed from a dielectric material different from a material of the dielectric barrier.

10. A semiconductor device, comprising:
a first stacked set of field effect transistors (FETs), including a first top FET with a top work function metal layer and a first bottom FET with a bottom work function metal layer;
a second stacked set of FETs, including a second top FET and a second bottom FET; and
a dielectric barrier between the first stacked set of FETs and the second stacked set of FETs, the dielectric barrier having a narrower width between the first top FET and the second top FET than between the first bottom FET and the second bottom FET, the top work function metal layer having a greater thickness between a channel of the first top FET and the dielectric barrier than a thickness of the bottom work function metal layer between a channel of the first bottom FET and the dielectric barrier.

11. The semiconductor device of claim 10, wherein the bottom work function metal layer has a different polarity as compared to the top work function metal layer.

12. The semiconductor device of claim 10, wherein the top work function metal layer is in direct contact with the bottom work function metal layer.

13. The semiconductor device of claim 10, wherein the dielectric barrier is in direct contact with the top work function metal layer and the bottom work function metal layer.

14. The semiconductor device of claim 10, wherein the top work function metal layer has a second thickness in a region between the dielectric barrier and a dielectric separation layer that separates the first top FET from the first bottom FET, the second thickness being the same as the thickness of the bottom work function metal layer between the first bottom FET and the dielectric barrier.

15. The semiconductor device of claim 10, wherein the dielectric barrier has a stepped profile between a narrower top portion and a thicker bottom portion.

16. The semiconductor device of claim 15, wherein a step of the stepped profile is at a height between the first top FET and the first bottom FET.

17. The semiconductor device of claim 10, further comprising a shallow trench isolation (STI) structure in a substrate between the first stacked set of FETs and the second stacked set of FETs that includes a dielectric material different from a material of the dielectric barrier.

18. A semiconductor device, comprising:
a first stacked set of field effect transistors (FETs), including a first top FET with a top work function metal layer and a first bottom FET with a bottom work function metal layer;
a second stacked set of FETs, including a second top FET and a second bottom FET;
a shallow trench isolation (STI) structure in a substrate between the first stacked set of FETs and the second stacked set of FETs; and
a dielectric barrier on the STI structure, between the first stacked set of FETs and the second stacked set of FETs, the dielectric barrier including a dielectric material different from a material of the STI structure and having a narrower width between the first top FET and the second top FET than between the first bottom FET and the second bottom FET, the top work function metal layer having a greater thickness between a channel of the first top FET and the dielectric barrier than a thickness of the bottom work function metal layer between a channel of the first bottom FET and the dielectric barrier.

19. The semiconductor device of claim 18, wherein the dielectric barrier has a stepped profile between a narrower top portion and a thicker bottom portion.

20. The semiconductor device of claim 19, wherein a step of the stepped profile is at a height between the first top FET and the first bottom FET.
